(19) United States
(12) Patent Application Publication
(10) Pub. No.: US 2026/0309789 A1
(43) Pub. Date: Oct. 8, 2026

(54) Module for detecting a battery level of charge, assembly comprising the module, and aircraft comprising the assembly

(71) Applicant: SAFRAN ELECTRICAL & POWER, Blagnac Cedex (FR)

(72) Inventor: Eric GUILLARD, MOISSY-CRAMAYEL (FR)

(21) Appl. No.: 19/479,861

(22) PCT Filed: May 13, 2024
(86) PCT No.: PCT/FR2024/050610

§ 371 Date: Oct. 29, 2025

(30) Foreign Application Priority Data
May 9, 2023 (FR) 2304612

(51) Int. Cl. G01R 31/374; B64D 35/021; B64D 45/00; G01R 31/3842; H01M 10/42

(52) U.S. Cl. CPC G01R 31/374; B64D 35/021; B64D 45/00; G01R 31/3842; H01M 10/4285; B64D 2045/0085

(57) ABSTRACT

A module for detecting a battery level of charge includes an ammeter comprising a magnetometer and a current-measuring device and a voltmeter having a first contact terminal, a second contact terminal, and a voltage-measuring device. The module also includes a temperature sensor and a housing intended to be attached to a first interconnection bar and a second interconnection bar, the housing having a receptacle in which the magnetometer is received, the receptacle being intended to be received in a measurement hole of the first interconnection bar. The module further includes a first attachment member for attaching the housing to the first interconnection bar, and a second attachment member for attaching the housing to the second interconnection bar.

### FIELD OF THE DISCLOSURE

The present disclosure relates to a module for detecting a battery level of charge, an assembly comprising the module and the battery, as well as an aircraft comprising the assembly and a powertrain electrically powered by the battery.

### PRIOR ART

Determining the level of charge of a battery is often useful, particularly in cases where the battery supplies electricity to the powertrain of an aircraft. It is known to determine the battery charge by connecting a voltmeter to the battery terminals, placing an ammeter between one of the battery terminals and a load connected to the battery, and measuring the temperature.

The present disclosure aims to improve the accuracy and robustness of the battery charge measurement and to facilitate integrating this measurement into an assembly that distributes the electrical energy from the battery, while minimizing the risk of failure.

### STATEMENT OF THE DISCLOSURE

For this purpose, in accordance with the present disclosure, a module for detecting a battery level of charge is proposed which comprises a housing and a subassembly, said subassembly comprising an ammeter, a voltmeter, and a temperature sensor, wherein:
the housing is intended to be attached to a first interconnection bar and a second interconnection bar which are powered by a battery, the subassembly being held in the housing,
the ammeter comprises a magnetometer and a current-measuring device, the magnetometer being electrically connected to the current-measuring device and the current-measuring device being configured to transmit a current signal that is based on the current detected by the magnetometer,
the voltmeter comprises a first contact terminal, a second contact terminal, and a voltage-measuring device, the first contact terminal and the second contact terminal each being electrically connected to the voltage-measuring device, the voltage-measuring device being configured to transmit a voltage signal that is based on the potential difference between the first contact terminal and the second contact terminal,
the temperature sensor is configured to transmit a temperature signal that is based on of the temperature,
the housing has a receptacle in which the magnetometer is received, the receptacle being intended to be received in a measurement hole of the first interconnection bar, the receptacle having an electrically insulating outer surface,
the module further comprises a first attachment member and a second attachment member, the first attachment member being configured to attach the housing to the first interconnection bar and to hold the first contact terminal in electrical contact with the first interconnection bar, the second attachment member being configured to attach the housing to the second interconnection bar and to hold the second contact terminal in electrical contact with the second interconnection bar.

The module can thus be fully implemented and tested before being connected to the battery.

According to another feature in accordance with the present disclosure, the module preferably further comprises a microcontroller, the microcontroller being electrically connected to the ammeter, the voltmeter, and the temperature sensor in order to receive the current signal, the voltage signal, and the temperature signal, the microcontroller being configured to emit an output signal that is based on the current signal, the voltage signal, and the temperature signal.

According to a complementary feature, the output signal successively comprises (multiplexed) the current signal, the voltage signal, and the temperature signal.

According to another feature in accordance with the present disclosure, the module preferably further comprises a connector, the connector being held on the housing and the connector being electrically connected to the microcontroller in order to receive the output signal.

The housing can thus be quickly connected in order to transmit information for determining the battery level of charge.

According to another feature in accordance with the present disclosure, the housing preferably has an internal space enclosing the ammeter, the voltmeter, and the temperature sensor.

The housing thus creates a segregation between the high voltage and the low voltage, the high voltage being external to the housing.

According to yet another feature in accordance with the disclosure, the receptacle is preferably formed by a tubular portion made of electrically insulating material.

The housing is thus simple to create, the magnetometer can be easily inserted into the measurement hole, and the magnetometer is mechanically protected and electrically isolated from the first interconnection bar in an effective manner.

Preferably, the module further presents the following features:
the subassembly forms a first subassembly (the ammeter forms a first ammeter, the magnetometer forms a first magnetometer, the current-measuring device forms a first current-measuring device, the current signal forms a first current signal, the voltmeter forms a first voltmeter, the first contact terminal forms a first first contact terminal, the second contact terminal forms a second first contact terminal, the voltage-measuring device forms a first voltage-measuring device, the voltage signal forms a first voltage signal, the temperature sensor forms a first temperature sensor, the temperature signal forms a first temperature signal, the output signal forms a first output signal, the receptacle forms a first receptacle, the measurement hole forms a first measurement hole, the outer surface forms a first outer surface, the first attachment member forms a first first attachment member, and the second attachment member forms a second first attachment member),
the module comprises a second subassembly that is distinct from the first subassembly, the second subassembly being held in the housing and comprising a second ammeter, a second voltmeter, and a second temperature sensor,
the second ammeter comprises a second magnetometer and a second current-measuring device, the second magnetometer being electrically connected to the second current-measuring device and the second current-measuring device being configured to transmit a second current signal that is based on the current detected by the second magnetometer,
the second voltmeter comprises a first second contact terminal, a second second contact terminal, and a second voltage-measuring device, the first second contact terminal and the second second contact terminal each being electrically connected to the second voltage-measuring device, the second voltage-measuring device being configured to transmit a second voltage signal that is based on the potential difference between the first second contact terminal and the second second contact terminal,
the second temperature sensor is configured to transmit a second temperature signal that is based on the temperature,
the housing has a second receptacle in which the second magnetometer is received, the second receptacle being intended to be received in a second measurement hole of the second interconnection bar, the second receptacle having a second electrically insulating outer surface, and
the module further comprises a first second attachment member and a second second attachment member, the first second attachment member being configured to attach the housing to the first interconnection bar and to hold the first second contact terminal in electrical contact with the first interconnection bar, the second second attachment member being configured to attach the housing to the second interconnection bar and to hold the second second contact terminal in electrical contact with the second interconnection bar.

Thus, without complicating the attachment or the electrical connection, the module offers a dual measurement system which allows providing information for determining the level of charge of the battery, in a manner such that if one of the systems fails, the information for determining the level of charge can still be provided by the other.

The present disclosure further relates to an assembly comprising, in addition to the aforementioned module, the first interconnection bar and the second interconnection bar. The assembly has the following features:
the first interconnection bar comprises the measurement hole, in which the magnetometer is arranged, the receptacle being arranged between the magnetometer and the first interconnection bar,
the first attachment member attaches the housing to the first interconnection bar and holds the first contact terminal in contact with the first interconnection bar, and
the second attachment member attaches the housing to the second interconnection bar and holds the second contact terminal in contact with the second interconnection bar.

The attachment of the module to the first interconnection bar and to the second interconnection bar creates the electrical connection of the module to the first interconnection bar and second interconnection bar, such that the connection to the battery is rapid and low-risk.

In various embodiments of the assembly according to the disclosure, one or more of the following arrangements may further optionally be used:

The first attachment member comprises a first attachment screw having a first screw head and a first threaded portion, the first threaded portion being screwed into the first interconnection bar and the first contact terminal being pressed between the first screw head and the first interconnection bar, and the second attachment member comprises a second attachment screw having a second screw head and a second threaded portion, the second threaded portion being screwed into the second interconnection bar and the second contact terminal being pressed between the second screw head and the second interconnection bar.

The assembly further comprises the battery, the battery comprising a first terminal and a second terminal, the first terminal being electrically connected to the first interconnection bar and the second terminal being electrically connected to the second interconnection bar.

This disclosure also relates to an aircraft comprising, in addition to the aforementioned assembly, a control member and a powertrain that is electrically powered by the battery via the control member.

The aircraft thus satisfies the stringent aeronautical requirements relating to reliability and safety.

### BRIEF DESCRIPTION OF FIGURES

Other features and advantages of the present disclosure will become apparent from the following detailed description, referring to the appended drawings in which:

FIG. 1 schematically represents an aircraft comprising an assembly and a powertrain,

FIG. 2 schematically represents the assembly comprising a module, a first interconnection bar, and a second interconnection bar,

FIG. 3 is a section view along the line labeled III-III in FIG. 1,

FIG. 4 is a section view along the line labeled IV-IV in FIG. 1.

### DETAILED DESCRIPTION OF THE DISCLOSURE

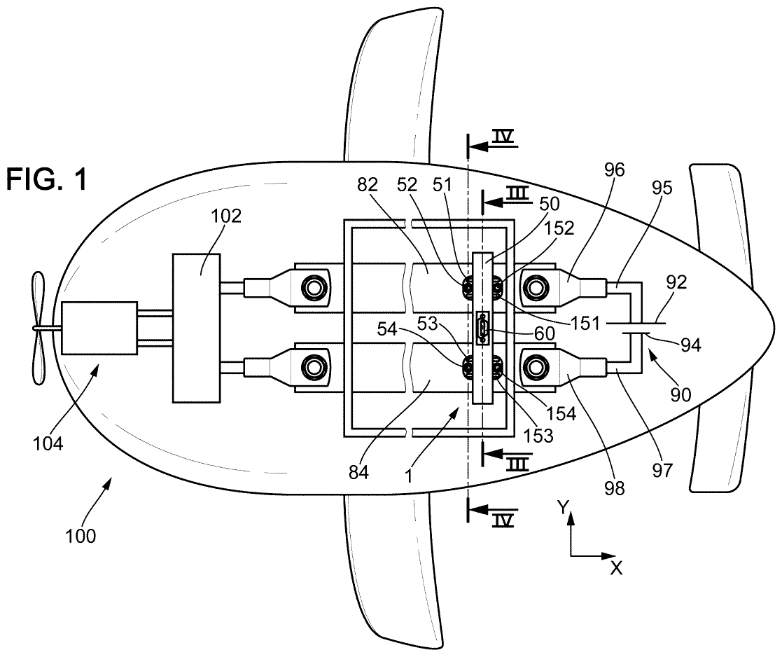

FIGS. 1 to 4 illustrate an aircraft 100 comprising an assembly 80, a control member 102, and a powertrain 104.

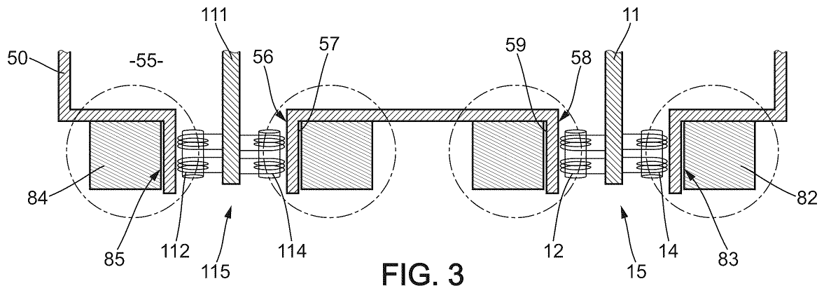

As illustrated in particular in FIGS. 1 and 3, the assembly 80 comprises a module 1, a first interconnection bar 82, a second interconnection bar 84, and a battery 90. The first interconnection bar 82 and the second interconnection bar 84 extend substantially in a longitudinal direction X. The first interconnection bar 82 has a first measurement hole 83. The first measurement hole 83 is cylindrical, of circular cross-section, preferably a through-hole, and made substantially in the middle of the first interconnection bar 82, in a transverse direction Y perpendicular to the longitudinal direction X. The first measurement hole 83 extends perpendicularly to the longitudinal direction X and to the transverse direction Y. The second interconnection bar 84 has a second measurement hole 85. The second measurement hole 85 is cylindrical, of circular cross-section, preferably a through-hole, and made substantially in the middle of the second interconnection bar 84, in the transverse direction Y. The second measurement hole 85 extends perpendicularly to the longitudinal direction X and to the transverse direction Y.

The battery 90 comprises a first terminal 92 and a second terminal 94. The first terminal 92 is electrically connected to the first interconnection bar 82 by means of a first input wire 95 and a first input terminal 96. The second terminal 94 is electrically connected to the second interconnection bar 84 by means of a second input wire 97 and a second input terminal 98. The first interconnection bar 82 and the second interconnection bar 84 each preferably comprise layers of copper, or at least of an electrically conductive material, separated by thin dielectric materials, laminated into a one-piece element.

The powertrain 104 comprises an electric motor and a propeller. The control member 102 is connected to the first interconnection bar 82 by a first output terminal and a first output wire, and to the second interconnection bar 84 by a second output terminal and a second output wire. The control member 102 is connected to the electric motor by a first electrical supply wire and a second electrical supply wire.

The module 1 comprises a housing 50, a connector 60, a first subassembly 70, and a second subassembly 170. The housing 50 is made of an electrically insulating material, in particular a plastic. The housing 50 has an internal space 55 delimited by the walls of the housing.

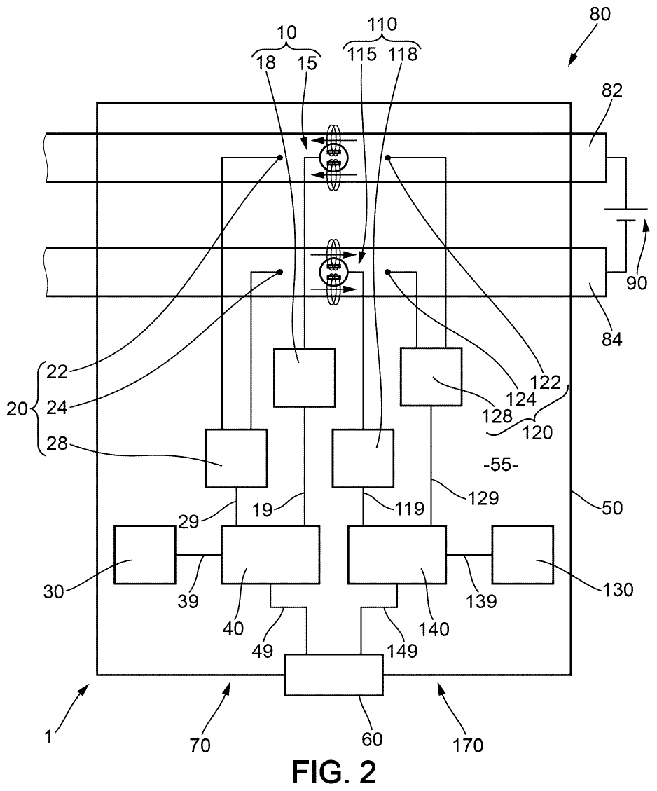

The first subassembly 70 is arranged in the internal space 55 held in the housing 50 and comprises a first ammeter 10, a first voltmeter 20, a first temperature sensor 30, and a first microcontroller 40, as illustrated in particular in FIG. 2.

The first ammeter 10 comprises a first magnetometer 15 and a first current-measuring device 18. As illustrated in particular in FIG. 3, the first magnetometer 15 comprises a first first magnetic field sensor 12 and a second first magnetic field sensor 14. The first first magnetic field sensor 12 and the second first magnetic field sensor 14 are held on a first printed circuit board 11. The first magnetometer 15 is arranged in the first measurement hole 83. The flow of current in the first interconnection bar 82 on either side of the first measurement hole 83 generates magnetic fields which are detected by the first first magnetic field sensor 12 and the second first magnetic field sensor 14. The first first magnetic field sensor 12 and the second first magnetic field sensor 14 are electrically connected to the first current-measuring device 18. The first current-measuring device 18 is preferably arranged on the first printed circuit board 11. The first current-measuring device 18 transmits a first current signal 19 that is based on the magnetic field generated by the current flowing in the first interconnection bar 82 and detected by the first magnetometer 15. The first ammeter 10 is in particular of the type marketed by Texas Instruments® under the reference DRV425.

The first voltmeter 20 comprises a first first contact terminal 22, a second first contact terminal 24, and a first voltage-measuring device 28. The first first contact terminal 22 and the second first contact terminal 24 are each electrically connected to the first voltage-measuring device 28. The first voltage-measuring device 28 is configured to transmit a first voltage signal 29 that is based on the potential difference between the first first contact terminal 22 and the second first contact terminal 24.

The first temperature sensor 30 is configured to transmit a first temperature signal 39 that is based on the temperature in the internal space 55 where the first temperature sensor 30 is located.

The first microcontroller 40 is electrically connected to the first ammeter 10, to the first voltmeter 20, and to the first temperature sensor 30, in order to receive the first current signal 19, the first voltage signal 29, and the first temperature signal 39. The first microcontroller 40 is configured to transmit, to the connector 60, a first output signal 49 that is based on the first current signal 19, the first voltage signal 29, and the first temperature signal 39. More precisely, the first microcontroller 40 preferably comprises a data bus, in particular a CAN (Controller Area Network) type of data bus, in order to successively transmit (in a multiplexed manner) the first current signal 19, the first voltage signal 29, and the second temperature signal 39, which are possibly recalibrated. Alternatively, the first microcontroller 40 could determine the level of charge of the battery 90 from the first current signal 19, the first voltage signal 29, and the first temperature signal 39, such that the first output signal 49 would contain information about the level of charge of the battery 90.

The second subassembly 170 is held in the housing 50 and comprises a second ammeter 110, a second voltmeter 120, a second temperature sensor 130, and a second microcontroller 140, as illustrated in particular in FIG. 2.

The second ammeter 110 comprises a second magnetometer 115 and a second current-measuring device 118. As illustrated in particular in FIG. 3, the second magnetometer 115 comprises a first second magnetic field sensor 112 and a second second magnetic field sensor 114. The first second magnetic field sensor 112 and the second second magnetic field sensor 114 are held on a second printed circuit board 111. The second magnetometer 115 is arranged in the second measurement hole 85. The flow of current in the second interconnection bar 84 on either side of the second measurement hole 85 generates magnetic fields which are detected by the first second magnetic field sensor 112 and the second second magnetic field sensor 114. The first second magnetic field sensor 112 and the second second magnetic field sensor 114 are electrically connected to the second current-measuring device 118. The second current-measuring device 118 is preferably arranged on the second printed circuit board 111. The second current-measuring device 118 transmits a second current signal 119 that is based on the magnetic field generated by the current flowing in the second interconnection bar 84 and detected by the second magnetometer 115. The second ammeter 110 is preferably identical to the first ammeter 10.

The second voltmeter 20 comprises a first second contact terminal 122, a second second contact terminal 124, and a second voltage-measuring device 128. The first second contact terminal 122 and the second second contact terminal 124 are each electrically connected to the second voltage-measuring device 128. The second voltage-measuring device 128 is configured to transmit a second voltage signal 129 that is based on the potential difference between the first second contact terminal 122 and the second second contact terminal 124.

The second temperature sensor 130 is configured to transmit a second temperature signal 139 that is based on the temperature in the internal space 55 where the second temperature sensor 130 is located.

The second microcontroller 140 is electrically connected to the second ammeter 110, to the second voltmeter 120, and to the second temperature sensor 130, in order to receive the second current signal 119, the second voltage signal 129, and the second temperature signal 139. The second microcontroller 140 is configured to transmit, to the connector 60, a second output signal 149 that is based on the second current signal 119, the second voltage signal 129, and the second temperature signal 139. More precisely, the second microcontroller 140 preferably comprises a data bus, in particular a CAN (Controller Area Network) type of data bus, in order to successively transmit (in a multiplexed manner) the second current signal 119, the first voltage signal 129, and the second temperature signal 139. Alternatively, the second microcontroller 140 could determine the level of charge of the battery 90 from the second current signal 119, the second voltage signal 129, and the second temperature signal 139, such that the second output signal 149 would contain information about the level of charge of the battery 90.

As illustrated in particular in FIG. 3, the housing 50 comprises a first receptacle 58 and a second receptacle 56. The first receptacle 58 is tubular with a circular cross-section, extends perpendicularly to the longitudinal direction X and to the transverse direction Y, and has a first outer surface 59 with a circular cross-section. The first receptacle 58 is tightly received in the first measurement hole 83, the first outer surface 59 extending substantially in contact with the first interconnection bar 82, in order to position the first magnetometer 15 relative to the first measurement hole 83 in the longitudinal direction X and transverse direction Y. The first receptacle 58 completely traverses the first interconnection bar 82, in order to avoid unexpected electrical contact between the first interconnection bar 82 and the first magnetometer 15. The second receptacle 56 is tubular with a circular cross-section, extends perpendicularly to the longitudinal direction X and transverse direction Y, and has a second outer surface 57 with a circular cross-section. The second receptacle 56 is tightly received in the second measurement hole 85, the second outer surface 57 extending substantially in contact with the second interconnection bar 84, in order to position the second magnetometer 115 relative to the second measurement hole 85 in the longitudinal direction X and transverse direction Y. The second receptacle 56 completely traverses the second interconnection bar 84, in order to avoid unexpected electrical contact between the second interconnection bar 84 and the second magnetometer 115.

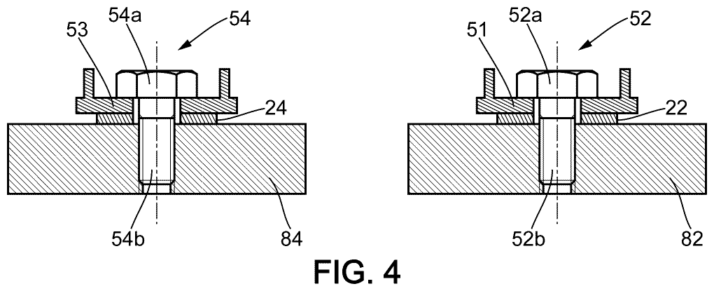

As illustrated in particular in FIGS. 1 and 4, the module 1 further comprises a first first attachment member 52 and a second first attachment member 54, the first first attachment member 52 attaching the housing 50 to the first interconnection bar 82. The first first attachment member 82 comprises a first first attachment screw having a first screw head 52a and a first threaded portion 52b. The first threaded portion 52b is screwed into the first interconnection bar 82. The housing 50 has a first first attachment lug 51. The first first attachment lug 51 is clamped between the first screw head 52a and the first interconnection bar 82. The first first contact terminal 22 is pressed between the first screw head 52a and the first interconnection bar 82. In the illustrated embodiment, the first first contact terminal 22 is arranged between the first first attachment lug 51 and the first interconnection bar 82, such that the first first contact terminal 22 is directly in contact with the first interconnection bar 82. Alternatively, the first first contact terminal 22 could be arranged between the first screw head 52a and the first first attachment lug 51, the electrical connection between the first first contact terminal 22 and the first interconnection bar 82 then being established by means of the first first attachment screw 51.

The second first attachment member 52 comprises a second first attachment screw having a second screw head 54a and a second threaded portion 54b. The second threaded portion 54b is screwed into the second interconnection bar 84. The housing 50 has a second first attachment lug 53. The second first attachment lug 53 is clamped between the second screw head 54a and the second interconnection bar 84. The second first contact terminal 24 is pressed between the second screw head 54a and the second interconnection bar 84. In the illustrated embodiment, the second first contact terminal 24 is arranged between the second first attachment lug 53 and the second interconnection bar 84, such that the second first contact terminal 24 is directly in contact with the second interconnection bar 84. Alternatively, the second first contact terminal 24 could be arranged between the second screw head 54a and the second first attachment lug 53, the electrical connection between the second first contact terminal 24 and the second interconnection bar 84 then being established by means of the second attachment screw.

As illustrated in particular in FIG. 1, the module 1 further comprises a first second attachment member 152 and a second second attachment member 154, and the housing 50 further comprises a first second attachment lug 151 and a second second attachment lug 153. The first second attachment member 152 attaches the first second attachment lug 151 to the first interconnection bar 82 and the second second attachment member 152 attaches the second second attachment lug 153 to the second interconnection bar 84. The first first attachment lug 51 and the first second attachment lug 153 are arranged on either side of the housing 50. The second first attachment lug 53 and the second second attachment lug 153 are arranged on either side of the housing 50. The first second attachment member 152 is similar to the first first attachment member 52. The first second attachment member 152 holds the first second attachment lug 151 on the first interconnection bar 82 and maintains the electrical contact of the first second contact terminal 122 with the first interconnection bar 82, in a manner similar to that described above in relation to the first first attachment member 52. The second second attachment member 154 is similar to the second first attachment member 54. The second second attachment member 154 holds the second second attachment lug 153 on the second interconnection bar 84 and maintains the electrical contact of the second second contact terminal 124 with the second interconnection bar 84, in a manner similar to that described above in relation to the second first attachment member 54.

The control member 102 is connected to the module 1 by the connector 60. Thus, the control member 102 receives first information from the first subassembly 70, for determining the level of charge of the battery 90, namely the current in the first interconnection bar 82 detected by the first ammeter 10, the potential difference between the first interconnection bar 82 and the second interconnection bar 84 detected by the first voltmeter 20, and the temperature detected by the first temperature sensor 30. The control member 102 then determines a first level of charge of the battery 90. Alternatively, the control member 102 receives the information about a first level of charge of the battery 90 from the first subassembly 70.

The control member 102 receives second information from the second subassembly 170, for determining the level of charge of the battery 90, namely the current in the second interconnection bar 84 detected by the second ammeter 110, the potential difference between the first interconnection bar 82 and the second interconnection bar 84 detected by the second voltmeter 120, and the temperature detected by the second temperature sensor 130. The control member 102 then determines a second level of charge of the battery 90. Alternatively, the control member 102 receives the information about a second level of charge of the battery 90 from the first subassembly 70.

1. A module for detecting a level of charge of a battery, comprising a housing and a subassembly, said subassembly comprising an ammeter, a voltmeter, and a temperature sensor, wherein:
the housing is intended to be attached to a first interconnection bar and a second interconnection bar which are powered by a battery, the subassembly being held in the housing,
the ammeter comprises a magnetometer and a current-measuring device, the magnetometer being electrically connected to the current-measuring device and the current-measuring device being configured to transmit a current signal that is based on the current detected by the magnetometer,
the voltmeter comprises a first contact terminal, a second contact terminal, and a voltage-measuring device, the first contact terminal and the second contact terminal each being electrically connected to the voltage-measuring device, the voltage-measuring device being configured to transmit a voltage signal that is based on the potential difference between the first contact terminal and the second contact terminal,
the temperature sensor is configured to transmit a temperature signal that is based on the temperature,
the housing has a receptacle in which the magnetometer is received, the receptacle being intended to be received in a measurement hole of the first interconnection bar, the receptacle having an electrically insulating outer surface,
the module further comprises a first attachment member and a second attachment member, the first attachment member being configured to attach the housing to the first interconnection bar, and to hold the first contact terminal in electrical contact with the first interconnection bar, the second attachment member being configured to attach the housing to the second interconnection bar and to hold the second contact terminal in electrical contact with the second interconnection bar.

2. The module according to claim 1 wherein the module further comprises a microcontroller, the microcontroller being electrically connected to the ammeter, the voltmeter, and the temperature sensor in order to receive the current signal, the voltage signal, and the temperature signal, the microcontroller being configured to emit an output signal that is based on the current signal, the voltage signal, and the temperature signal.

3. The module according to claim 2 wherein the module further comprises a connector, the connector being held on the housing and the connector being electrically connected to the microcontroller in order to receive the output signal.

4. The module according to claim 1, wherein the housing has an internal space enclosing the ammeter, the voltmeter, and the temperature sensor.

5. The module according to claim 1, wherein the receptacle is formed by a tubular portion made of electrically insulating material.

6. The module according to claim 1, wherein:
the subassembly forms a first subassembly,
the module comprises a second subassembly that is distinct from the first subassembly, the second subassembly being held in the housing and comprising a second ammeter, a second voltmeter, and a second temperature sensor,
the second ammeter comprises a second magnetometer and a second current-measuring device, the second magnetometer being electrically connected to the second current-measuring device and the second current-measuring device being configured to transmit a second current signal that is based on the current detected by the second magnetometer,
the second voltmeter comprises a first second contact terminal, a second second contact terminal, and a second voltage-measuring device, the first second contact terminal and the second second contact terminal each being electrically connected to the second voltage-measuring device, the second voltage-measuring device being configured to transmit a second voltage signal that is based on the potential difference between the first second contact terminal and the second second contact terminal,
the second temperature sensor is configured to transmit a second temperature signal that is based on the temperature,
the housing has a second receptacle in which the second magnetometer is received, the second receptacle being intended to be received in a second measurement hole of the second interconnection bar the second receptacle having a second electrically insulating outer surface, and
the module further comprises a first second attachment member and a second second attachment member, the first second attachment member being configured to attach the housing to the first interconnection bar and to hold the first second contact terminal in electrical contact with the first interconnection bar, the second second attachment member being configured to attach the housing to the second interconnection bar and to hold the second second contact terminal in electrical contact with the second interconnection bar.

7. An assembly comprising the module according to claim 1, the first interconnection bar, and the second interconnection bar, wherein:
the first interconnection bar comprises the measurement hole, in which the magnetometer is arranged, the receptacle being arranged between the magnetometer and the first interconnection bar,
the first attachment member attaches the housing to the first interconnection bar and holds the first contact terminal in contact with the first interconnection bar, and
the second attachment member attaches the housing to the second interconnection bar and holds the second contact terminal in contact with the second interconnection bar.

8. The assembly according claim 7, wherein:
the first attachment member comprises a first attachment screw having a first screw head and a first threaded portion, the first threaded portion being screwed into the first interconnection bar and the first contact terminal being pressed between the first screw head and the first interconnection bar, and
the second attachment member comprises a second attachment screw having a second screw head and a second threaded portion the second threaded portion being screwed into the second interconnection bar and the second contact terminal being pressed between the second screw head and the second interconnection bar.

9. The assembly according to claim 7 wherein the assembly further comprises the battery, the battery comprising a first terminal and a second terminal, the first terminal being electrically connected to the first interconnection bar and the second terminal being electrically connected to the second interconnection bar.

10. An aircraft comprising the assembly according to claim 9, a control member, and a powertrain that is electrically powered by the battery via the control member.
